(19) United States
(12) Patent Application Publication
(10) Pub. No.: US 2006/0150892 A1
(43) Pub. Date: Jul. 13, 2006

(54) Processes Involving the Use of Antisolvent Crystallisation

(75) Inventor: Mateo Josef Jacques Mayer, Amersfoort (NL)

Correspondence Address: OLIFF & BERRIDGE, PLC, P.O. BOX 19928, ALEXANDRIA, VA, 22320, US

(73) Assignee: AKZO Nobel N.V., BM Arnhem (NL)

(21) Appl. No.: 10/552,733

(22) PCT Filed: Apr. 23, 2004
(86) PCT No.: PCT/EP04/04383

§ 371 Date: Jan. 6, 2006

Related U.S. Application Data
(60) Provisional application No. 60/466,389, filed on Apr. 29, 2003.
(60) Provisional application No. 60/486,473, filed on Jul. 11, 2003.

(30) Foreign Application Priority Data
Oct. 21, 2003 (EP) 03078314.6

(51) Int. Cl. H01L 21/322; C30B 15/14

(52) U.S. Cl. 117/2; 117/3

(57) ABSTRACT

The present invention pertains to a process to make salt compositions comprising the steps of feeding water to a salt source to form an aqueous solution comprising said salt, feeding said aqueous solution to a crystalliser/settler, contacting said aqueous solution with one or more antisolvents which force the salt to crystallise, with said antisolvents exhibiting crystal growth inhibiting properties and/or crystallisation and scale inhibiting properties, and/or where one or more crystal growth inhibitors are present either in the antisolvents or the aqueous solution and/or one or more scaling inhibitors are present either in the antisolvents or the aqueous solution, feeding an overflow of the crystalliser/settler comprising one or more antisolvents and an aqueous salt solution to a nanofiltration unit comprising a membrane to separate the one or more antisolvents from the aqueous salt solution, removing the crystallised salt in an aqueous slurry, optionally, recycling the one or more antisolvents to the crystalliser/settler, and optionally, recycling water from the slurry to the first dissolution step and/or to the crystalliser/settler. Preferably, the process is a closed loop process and the salt is sodium chloride. Preferably, the process further comprises a reverse osmosis step before the overflow of the crystalliser/settler is fed to a nanofiltration unit.

This is a National Stage of Application No. PCT/EP2004/004383 filed Apr. 23, 2004, which claims the benefit of U.S. Provisional Applications No. 60/466,389 filed Apr. 29, 2003 and No. 60/486,473 filed Jul. 11, 2003 and European Patent Application No. 03078314.6 filed Oct. 21, 2003. The entire disclosure of the prior applications is hereby incorporated by reference herein in its entirety.

The present invention relates to a process to make inorganic salt compositions comprising the crystallisation of said salt from a crude aqueous solution using an antisolvent, and to a process for the preparation of drinking and/or process water.

Many inorganic salts are made industrially from aqueous solutions produced by dissolving a natural source of the salt in water. The salt is usually obtained by crystallising it from the aqueous solution by evaporation of the water, which is generally accomplished using multiple-effect or vapour recompression evaporators. Multiple-effect systems typically contain three or more forced-circulation evaporating vessels connected in series. The steam produced in each evaporator is fed to the next one in the multiple-effect system to increase energy efficiency. Vapour recompression forced-circulation evaporators consist of a crystalliser, a compressor, and a vapour scrubber. The aqueous salt solution enters the crystalliser vessel, where salt is crystallised. Vapour is withdrawn, scrubbed, and compressed for reuse in the heater. Both recompression evaporators and multiple-effect evaporators are energy-intensive because of the water evaporation step involved. Furthermore, aqueous salt solutions produced by dissolving a natural source of said salt in water normally contain a quantity of contaminations. Therefore, additional purification steps of the salt solution prior to crystallisation, additional washing of the inorganic salt produced and/or energy-consuming drying steps have to be employed to reduce the levels of contaminants.

Said contaminations in aqueous salt solutions from a natural source comprise int. al. potassium, magnesium, calcium, and sulfate ions. Additionally, small concentrations of carbon dioxide, bicarbonate, and carbonate are present in the raw aqueous solution. During evaporative crystallisation in conventional evaporators (multiple-effect or vapour recompression installations), usually operated at elevated temperature, CaSO₄, CaSO₄.0.2H₂O, and CaCO₃ scaling is formed, especially at the surface of the heat exchangers. The reason for this scale formation is that due to evaporation of water, the aqueous salt solution becomes more concentrated, which results in CaSO₄ and CaCO₃ supersaturation, and the solubility of anhydrite (CaSO₄) and calcium carbonate decreases with increasing temperature. As a result of the scaling, the production capacity of the salt plant decreases with time, as does the energy efficiency of the process. After a production period that is typical for the quantity of contaminations in the aqueous solution and for the set-up of the conventional process, the evaporation installation needs to be cleaned, so the availability of the salt plant is also reduced. The most common procedure for dealing with the problems mentioned above is to purify the raw aqueous solution before it is fed to the evaporation plant. A different technology is the recycling of anhydrite crystals with a large specific surface in the evaporation plant, so that most CaSO₄ is precipitated onto the crystals instead of onto the heat exchangers. However, these extra process steps result in extra purification costs, additional handling, or a poor salt quality.

The above-mentioned problems also arise in conventional processes for the preparation of sodium chloride compositions. The conventional process to make sodium chloride and wet sodium chloride involves producing a brine by dissolving a natural source of NaCl in water and subsequent evaporative crystallisation of said brine. The brine will contain quantities of dissolved K, Br, SO₄, Mg, Sr and/or Ca, since these contaminations are typically present in natural NaCl sources. A disadvantage of such a process is that the salt obtained has imperfections in the crystal lattice and contains occlusions, i.e. small pockets of mother liquor of the evaporative crystallisation process which are present in cavities in the salt crystals. Due to these imperfections and occlusions, the (wet) salt, as well as the brine produced therefrom, is contaminated with compounds present in the mother liquor. In particular, the quantities of K, Br, SO₄, Mg, Sr and/or Ca that are carried over are quite high. Therefore, additional washing steps are required to reduce the quantities of contaminants as much as possible.

In addition to occlusions of mother liquor in the imperfect salt crystals, there is a second mechanism resulting in contaminations ending up in the salt. Potassium and bromide ions both have physical properties and dimensions that are close to those of sodium and chloride ions, respectively. This means that these ions are built into the salt crystal lattice. Depending on the nature and the number of imperfections in the crystal lattice, that is, imperfections on an ion scale, the process of building a potassium or bromide ion into the crystal lattice is enhanced or inhibited. Therefore, the partitioning coefficient of bromide, i.e. the content of bromide in the salt produced [mg/kg] over the concentration of bromide in the mother liquor [mg/l], depends on the crystallisation conditions. The same applies for the partitioning coefficient of potassium. It is also noted that the partitioning coefficients for potassium and bromide increase with temperature, which makes the conventional processes performed at elevated temperature less attractive.

It is known that antisolvent crystallisation can be an energy-saving alternative for the production of inorganic salts normally produced by evaporative crystallisation. In antisolvent crystallisation the salt is obtained by the addition of an antisolvent to an aqueous salt solution which induces crystallisation of the salt, followed by a filtration step. The antisolvent is usually recovered to allow the creation of a continuous, industrially useful process. In respect of this, antisolvents that are partially miscible with water are suitable. These antisolvents can be (partially) recovered from a spent mother liquor by increasing or decreasing its temperature to a value where the mutual solubilities of the antisolvent and the water are low, thus creating a two-phase system in which the two liquids can be easily separated from each other. The crystallisation can be carried out in either a single- or a two-phase system. In the single-phase system, the salt crystallises because of the introduction of the antisolvent into the aqueous salt solution, which reduces the solubility of the salt by binding of the water. In the two-phase system three phases co-exist in the crystalliser, i.e. a solid salt phase and antisolvent-rich and water-rich liquid phases. Here the driving force for crystallisation is created by the extraction of water from the aqueous phase into the organic antisolvent-rich phase, and by the dissolution of antisolvent in the aqueous phase.

A special antisolvent crystallisation process for inorganic salts is described by D. A. Weingaertner et al. in Ind. Eng. Res., 1991, Vol. 30, pages 490-501. Said antisolvent crystallisation process is an extractive crystallisation process wherein particular salts, such as sodium chloride and sodium carbonate, are recovered from their saturated aqueous solutions by the addition of an organic solvent. Solid salt is formed because water is transferred from the aqueous phase to the organic phase, resulting in direct shrinkage of the aqueous phase, and/or because of solvent entering the aqueous phase, resulting in diminished solubility of salt in that phase. Either way, precipitation and crystal growth of a solid salt phase take place, after which the salt is removed. The solvent is recovered by shifting the temperature to a level at which two liquid phases are formed, one solvent-rich and the other water-rich. Separation of these two phases then yields a relatively dry solvent phase and a water phase.

Three main factors that determine the quality of a salt product are the size distribution of the formed particles, the purity of the product, and the shape of the particles. However, a general drawback of antisolvent crystallisation methods is that due to the high supersaturations involved, contaminations tend to precipitate together with the salt. Moreover, the occurrence of agglomerates or morphological instabilities is often observed. Since the voids inside the agglomerates will be filled with mother liquor, these growth forms increase the extent of mother liquor entrapment. Therefore, contaminations which do not pose a problem when using evaporative crystallisation, such as antisolvent molecules, can become a problem as well. Hence, additional washing steps or recrystallisations are usually needed to obtain salt with the desired purity. Because of the high supersaturations typical of antisolvent crystallisation, the dominant mechanism for crystal formation is primary nucleation. As a result, most antisolvent crystallisations result in very small crystals and crystal aggregates. An important disadvantage of these crystal slurries is that they can hardly be separated from the mother liquor using centrifuges that are typical for the conventional multi-effect evaporation process. Consequently, washing of the salt slurry and separation of the salt slurry from the mother liquor in such a way that the moisture content of the slurry is below 10 percent by weight, which is typically needed, becomes a very costly step.

It is an object of the present invention to provide an improved salt crystallisation process which is less energy-consuming and less water-consuming than the conventional processes, while still resulting in the desired product quality.

Surprisingly, we have now found that an improved antisolvent crystallisation process makes it possible to produce inorganic salt compositions with a reduced level of contaminants using less energy and less water than conventional evaporation or antisolvent crystallisation processes.

In more detail: the process to make the high-purity salt compositions according to the present invention comprises the steps of
feeding water to a salt source to form an aqueous solution comprising said salt,
feeding said aqueous solution to a crystalliser/settler,
contacting said aqueous solution with one or more antisolvents which force the salt to crystallise, with at least one of said antisolvents exhibiting crystal growth inhibiting properties and/or scaling inhibiting properties,
and where if the antisolvents do not exhibit sufficient crystal growth inhibiting properties and/or sufficient scaling inhibiting properties, one or more crystal growth inhibitors are added to the antisolvents and/or to the aqueous solution, and/or one or more scaling inhibitors are added to the antisolvents and/or to the aqueous solution,
feeding an overflow of the crystalliser/settler comprising one or more antisolvents and an aqueous salt solution to a nanofiltration unit comprising a membrane to separate the one or more antisolvents from the aqueous salt solution,
removing the crystallised salt from the crystalliser/settler in an aqueous slurry,
optionally, recycling the one or more antisolvents to the crystalliser/settler, and
optionally, recycling water from the slurry to the first dissolution step and/or to the crystalliser/settler.

It is noted that the term contacting as used throughout this specification is meant to comprise any conventional technique for adding the antisolvent(s) to the aqueous solution comprising the inorganic salt, such that the antisolvent(s) and said aqueous solution are able to at least partially dissolve in one another, wherein partially means that in a 1:1 mixture of an antisolvent and water, at least 0.5 wt %, preferably at least 2 wt % of the antisolvent will dissolve in the aqueous solution, and/or that at least 0.5 wt %, preferably at least 2 wt % of water will dissolve in the antisolvent. It is furthermore noted that the term “membrane” which is placed inside a nanofiltration unit for separating the one or more antisolvents from the aqueous salt solution, as used throughout this specification, is meant any conventional membrane having a molecular weight cut-off of at least 100 Da, preferably at least 150 Da, more preferably at least 200 Da, and most preferably at least 250 Da, and wherein the molecular weight cut-off is at most 100,000 Da, preferably at most 25,000 Da, more preferably at most 10,000 Da, and most preferably at most 2,500 Da.

In a preferred embodiment, the antisolvent crystallisation process of the present invention is suitable for the preparation of high-purity salt. In general, additional purification steps or recrystallisation steps are not necessary when an antisolvent with crystal growth inhibiting properties and/or one or more crystal growth inhibitors are employed in the process according to the present invention. This is because the crystal growth inhibiting antisolvent and/or crystal growth inhibitor(s) prevent primary nucleation of salt crystals, which finally results in relatively coarse salt crystals (i.e. crystals with a diameter of about 300 microns) with a uniform crystal size distribution, which can be easily separated from the aqueous slurry, e.g. by use of a centrifuge. The narrow crystal size distribution makes it possible to also apply conventional centrifuges at relatively small average crystal sizes.

Said process is applicable for the crystallisation of inorganic salts. Preferably, said process is used for the crystallisation of inorganic salts usually produced by evaporative crystallisation. Furthermore, it is noted that the process can also be used to selectively remove contaminations from a solution, for example the removal of calcium sulfate from brine by application of an antisolvent specific for calcium sulfate. Also, the production of sodium sulfate from a sulfate-rich brine is possible by application of this technology. Preferably, the process is used for the crystallisation of alkali or alkaline earth salts of halides, phosphates, carbonates, sulfates, or nitrates. Most preferably, the process is used for the crystallisation of sodium chloride. Preferably, the sodium chloride used as raw material is rock salt and/or a subterraneous salt deposit. More preferably, it is a subterraneous salt deposit exploited by means of dissolution mining. The process may also be used for the crystallisation and purification of solar salt (salt or saturated brine obtained by evaporating water from brine using solar heat), including solar sea salt, which is typically obtained from sea water. It is noted that the term “sodium chloride” as used throughout this document is meant to denominate all types of sodium chloride of which more than 25 wt % is NaCl. Preferably, such sodium chloride contains more than 50 wt % of NaCl. More preferably, the sodium chloride contains more than 75 wt % of NaCl, while a sodium chloride containing more than 90 wt % of NaCl is most preferred.

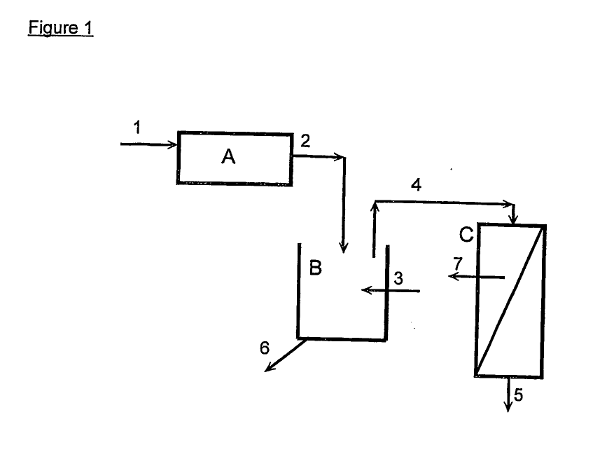

The present invention will now be explained in more detail with reference to a preferred embodiment as depicted in FIG. 1.

FIG. 1 is a schematic depiction of a preferred flow chart for the above-disclosed novel process. Water (1) is fed to a salt source (A), where it dissolves at least part of the salt. When the solution comes out of the source (2), it is preferably saturated with salt and generally will comprise contaminants, such as dissolved K, Br, SO₄, Mg, Sr and/or Ca ions. The (saturated) solution is fed to a conventional crystalliser/settler (B), which preferably comprises an inlet pipe. One or more antisolvents (3) are also fed to the crystalliser/settler (B). The crystalline salt composition formed is removed from the crystalliser/settler (B) as an aqueous slurry (6) and preferably fed to a centrifuge. Since said salt slurry (6) that is removed from the crystalliser/settler (B) by one or more outlets may still contain relatively large quantities of antisolvent, most preferably, before said salt slurry is fed to a centrifuge, it is fed to a washing leg. Especially if the salt slurry is to be used for electrolysis purposes, it is important to wash the adhered mother liquor, i.e. the residual solution which remains after the crystallised salt(s) have been removed, and/or antisolvent from the salt crystals.

This can be realised by feeding said salt slurry to a conventional washing leg operated with a raw aqueous salt solution or a purified aqueous salt solution as washing medium. It is noted that a purified aqueous salt solution can be produced by washing the salt crystals with water on a centrifuge. In this way, the production of washing brine is combined with an additional washing step on the centrifuge, while the filtrate of the centrifuge can be used as washing brine. The overflow (4) of the crystalliser/settler which comprises the combined antisolvent and aqueous salt solution is fed to a nanofiltration unit (C) comprising a membrane wherein the one or more antisolvents can be separated from the aqueous salt solution. Preferably, the membrane is permeable to salt and to the contaminations present in the aqueous solution, but not to antisolvent. After being separated from each other, the aqueous solution (5), which is undersaturated with salt, and the antisolvent (7) are removed from the nanofiltration unit. It is possible to remove traces of antisolvent in the aqueous solution (5) removed from the nanofiltration unit by the addition of adsorbents with a high specific surface area such as clay minerals, or by means of a conventional ion exchanger. Preferably, the recovered antisolvent (7) is reused by being recycled to the crystalliser/settler.

In a particularly preferred embodiment the process is a continuous, closed loop process wherein the aqueous solution filtered through the membrane, being undersaturated for salt, is recycled from the nanofiltration unit to the salt source. There it is used to dissolve more salt, thus producing a, preferably saturated, aqueous solution which can be fed to the crystalliser/settler. In an even more preferred embodiment, the crystalline salt composition is removed from the crystalliser/settler (B) and fed to a centrifuge as a slurry, after which the recycle of the centrifuge is recycled back into the crystalliser/settler and/or to the salt source. Such a process, hereinafter called a closed loop antisolvent crystallisation process, has the major advantage that there is no discharge of aqueous salt solution flows.

An antisolvent suitable for use in the process according to the present invention is a liquid compound or mixture of liquid compounds in which the salt to be crystallised is less soluble than in water at 20° C. Moreover, an antisolvent can be employed which is a gaseous or solid component. More particularly, the term “antisolvent” as used throughout this application is meant to include each component, liquid compound, or mixture of components and/or liquid compounds which leads to the crystallisation of 5 g or more of salt after the addition of 500 g of the antisolvent to 1,000 ml of saturated aqueous salt solution at a temperature between −10 and 110° C. The exact temperature at which said crystallisation is performed depends on the salt, the liquid compound(s) and/or component(s) used, and on the desired processing temperature. Preferably, one or more antisolvents which are fluid at 20° C. are used in the process according to the present invention. More preferably, a liquid compound which is an organic solvent, an ionic solvent, or an organic or inorganic complex is used as antisolvent. Most preferably, an organic solvent is used as the antisolvent. The testing temperature is the temperature at which the crystallisation according to the invention is conducted.

In a preferred embodiment, the antisolvent is used in an amount of at least 1 g per litre of saturated aqueous salt solution. More preferably, at least 50 g and most preferably, at least 200 g are used per litre of saturated aqueous salt solution.

Particularly preferred antisolvents for the antisolvent crystallisation process according to the invention are organic solvents which exhibit crystal growth inhibiting properties and/or scale inhibiting properties.

In order to determine whether or not an antisolvent has crystal growth inhibiting properties, the following tests can be used, with preferably test 3 being used, more preferably test 2, and most preferably test 1.
1) In a stirred glass beaker, 1 l of a saturated aqueous salt solution comprising 200 mg/l of bromide is heated to boiling point under atmospheric conditions and water is evaporated until a volume of 800 ml is obtained. The precipitated salt is filtered off, washed with 500 ml of acidified saturated aqueous salt solution (0.1 M HCl), centrifuged, and dried. Next, the quantity of occluded water is measured by heating the sample up to 700° C. while nitrogen is passed over it and subsequently performing a conventional coulometric titration. Furthermore, the quantity of bromide is determined (in mg Br per kg of dried salt) by conventional spectrophotometry measurements. Finally, the d50, i.e. the diameter at which 50 wt % of the crystals have a larger crystal diameter and 50 wt % of the crystals have a smaller crystal diameter, is determined. The crystal size distribution can be determined by means of conventional techniques such as sieve analysis and (light) microscopy. From the bromide content in the salt crystals and in the final mother liquor (which is about 200/0.8=250 mg/l) a partition coefficient is calculated. Said partition coefficient is the Br content in salt crystals (in mg/kg) divided by the Br content in the mother liquor (in mg/l). This is the blank experiment.
The above-described procedure is repeated using 10 g/l of an antisolvent and the obtained values for occluded water in the crystals, the partition coefficient, and the d50 value are compared to the ones obtained in the blank experiment. Preferably, 50 wt % antisolvent is used, based on the total weight of the reaction mixture. An antisolvent is considered to be a crystal growth inhibitor if the quantity of occluded water decreases by more than 5% and/or the partition coefficient decreases by more than 5% and/or the d50 value changes by more than 5%. Moreover, if analysis by means of a (light) microscope shows crystals with (111) faces, the antisolvent is also considered to have crystal growth inhibiting properties.
2) In a stirred glass beaker, 1 l of a saturated aqueous salt solution comprising 200 mg/l of bromide is heated to reflux. The boiling solution is then saturated again by the addition of extra salt. The saturated solution is then left in a hood at room temperature for 48 h. The precipitated salt is filtered off, washed with 500 ml of acidified brine (0.1 M HCl), centrifuged, and dried. Subsequently the quantity of occluded water is measured as described above for method 1. Furthermore, the quantity of bromide is determined in mg Br per kg of dried salt as described for method 1. Finally, the d50 is determined as explained above for method 1. This is the blank experiment.
The above-described procedure is repeated using 10 g/l of an antisolvent. Preferably, 50 wt % antisolvent is used, based on the total weight of the reaction mixture. The obtained values for occluded water in the crystals, the partition coefficient, and the d50 value are compared to the ones obtained in the blank experiment. An antisolvent is considered to be a crystal growth inhibitor if the quantity of occluded water decreases by more than 5% and/or the partition coefficient decreases by more than 5% and/or the d50 value changes by more than 5%. Moreover, if analysis by means of a (light) microscope shows crystals with (111) faces, the antisolvent is also considered to exhibit crystal growth inhibiting properties.
3) In a stirred glass beaker, 1 l of a saturated aqueous salt solution comprising 200 mg/l of bromide is left in a hood at room temperature for 1 week. The precipitated salt is filtered off, washed with 500 ml of saturated acidified aqueous salt solution (0.1 HCl), centrifuged, and dried. Again the quantity of occluded water, the quantity of bromide, and the d50 value are determined as described above for method 1. This is the blank experiment.
The above-described procedure is repeated using 10 g/l of an antisolvent. Preferably, 50 wt % antisolvent is used, based on the total weight of the reaction mixture. The obtained values for occluded water in the crystals, the partition coefficient, and the d50 value are compared to the ones obtained in the blank experiment. An antisolvent is considered to be a crystal growth inhibitor if the quantity of occluded water decreases by more than 5% and/or the partition coefficient decreases by more than 5% and/or the d50 value increases by more than 5%. Moreover, if analysis by means of a (light) microscope shows crystals with (111) faces, the antisolvent is also considered to exhibit crystal growth inhibiting properties.

The term “antisolvent which exhibits scaling inhibiting properties” as used throughout this document means that the antisolvent inhibits both the crystallisation and the scaling of calcium and/or strontium salts. Preferably, said antisolvents inhibit the crystallisation and the scaling of magnesium and/or potassium salts too. This has the advantage that fouling of the membrane in the nanofiltration unit will be greatly reduced and that brine purification by use of chemicals can be omitted. Whether or not an antisolvent exhibits scale inhibiting properties can be determined using one of the following three tests. If in one of these tests, preferably in two or more of these tests, and most preferably in all of these tests an antisolvent is considered to be a scaling inhibitor, said antisolvent is suitable for use in the process according to the present invention.
1) Antisolvent tests for the inhibition of crystallisation and scaling of SrCO₃ and/or CaCO₃:
   a) 1 l of a saturated aqueous salt solution comprising 360 meq/l of SO₄, 2.0 meq/l of Ca, 0.1 meq/l Sr, 10 meq/l of CO₃, 6 meq/l of OH, and 120 meq/l of Br is stirred and heated to boiling point under atmospheric conditions. Water is evaporated until a volume of 500 ml is obtained. The reaction mixture is filtered over a 0.2 micron filter and the quantity of dissolved Ca, Sr, and CO₃ in the mother liquor determined by means of conventional ICP (Inductively Coupled Plasma) spectrometry (for the quantity of Ca and Sr ions) and titrimetry (for the quantity of CO₃). This is the blank experiment. The procedure is repeated using 10 g/l of antisolvent. The quantities of Ca, Sr, and CO₃ in the mother liquor are now compared to the quantities of Ca, Sr, and CO₃ in the mother liquor as observed for the blank experiment. An antisolvent is considered to have scale inhibiting properties if the quantities of dissolved Ca and/or Sr and/or CO₃ increase by more than 5%.
   b) To 1 l of a saturated aqueous salt solution comprising 360 meq/l of SO₄, 2.0 meq/l of Ca, 0.1 meq/l Sr, 10 meq/l of CO₃, 6 meq/l of OH, and 120 meq/l of Br are added 5 g of Socal® P2 ex Solvay Chemicals (i.e. CaCO₃ crystals). The mixture is stirred and heated to boiling point under atmospheric conditions. Water is evaporated until a volume of 500 ml is obtained. The reaction mixture is filtered over a 0.2 micron filter and the quantities of dissolved Ca, Sr, and CO₃ in the mother liquor are determined. This is the blank experiment. The procedure is repeated using 10 g/l of antisolvent. The quantities of Ca, Sr, and CO₃ in the mother liquor are now compared to the quantities of Ca, Sr, and CO₃ in the mother liquor as observed for the blank experiment. An antisolvent is considered to have scale inhibiting properties if the quantity of dissolved Ca and/or Sr and/or CO₃ increases by more than 5%.
   c) A 10 l saturated aqueous salt solution with a pH value of 7 comprising 75 meq/l of Ca, 2 meq/l of Sr and 75 meq/l of SO₄, and 0.1 mol of sodium carbonate is filtered over a 1 m² nanofiltration membrane over a period of 15 h. The permeate flow is recycled back to the high-pressure side of the membrane. After 15 h, the flux through the membrane at constant pressure is determined. This is the blank experiment. The procedure is now repeated with a saturated aqueous salt solution comprising 1 g/l of antisolvent. The permeate flow is recycled back to the high-pressure side of the membrane, where the antisolvent is present. An antisolvent is considered to have scale inhibiting properties if the flux has increased by more than 5% compared to the flux observed in the blank experiment.
   d) The same test as test 1a, but at a temperature of 90° C. and with the addition of 100 mg/l of Socal® P2 seeds ex Solvay Chemicals to the aqueous salt solution. If the boiling point of the antisolvent-brine mixture is lower than 90° C., both the blank test and the test with antisolvent are performed at the boiling point of the mixture.
   e) The same test as test 1d, but performed at 20° C.
   f) The same test as test 1d, but without SO₄ ions present in the saturated aqueous salt solution.

Preferably, test 1f is used, more preferably test 1e, more preferably still test 1d, even more preferably test 1c, even more preferably still test 1b, and most preferably, test 1a is used in order to test an antisolvent for its scale inhibiting properties.
2) Antisolvent test for the inhibition of crystallisation and scaling of CaSO₄ (anhydrite): A saturated aqueous salt solution comprising 100 meq/l of Ca and 100 meq/l of SO₄ is heated to a temperature of 100° C. (or up to the boiling point of the antisolvent-brine mixture) for 1 h with stirring in the presence of 5 g/l of anhydrite crystals. In order to prevent evaporation of the antisolvent, the test is performed at reflux conditions. Subsequently a sample is taken which is filtered. Then the quantity of dissolved Ca is determined by ICP and the quantity of dissolved SO₄ is determined by ion chromatography or titrimetry. This is the blank experiment. The above-described procedure is repeated using 1 g/l of antisolvent. An antisolvent is considered to have scale inhibiting properties if the quantity of Ca and/or SO₄ dissolved in the mother liquor increases by more than 5% as compared to the blank experiment. Preferably, the pH is controlled and 10 meq/l OH is added.
3) Antisolvent test for the inhibition of crystallisation and scaling of CaSO₄.2H₂O (gypsum): A saturated aqueous salt solution comprising 150 meq/l of Ca and 150 meq/l of SO₄ is stirred at a temperature of 20° C. for 1 h in the presence of 5 g/l of gypsum crystals. Subsequently a sample is taken which is filtered. Then the quantity of dissolved Ca and SO₄ is determined as just-described for test 2. This is the blank experiment. The above-described procedure is repeated using 1 g/l of antisolvent. An antisolvent is considered to have scale inhibiting properties if the quantity of Ca and/or SO₄ dissolved in the mother liquor increases by more than 5%. Preferably, the pH is controlled and 10 meq/l OH is added.

Antisolvents which do not exhibit crystal growth inhibiting and/or scale inhibiting properties can also be used in the process according to the present invention, provided that at least an effective quantity of one or more crystal growth inhibitors and/or one or more scaling inhibitors is present either in the antisolvents or the aqueous phase.

Whether or not an additive is a crystal growth inhibitor can be determined using one of the following three tests, with preferably test 3 being used, more preferably test 2, and most preferably test 1.
1) In a stirred glass beaker, 1 l of a saturated aqueous salt solution comprising 200 mg/l of bromide is heated until a volume of 800 ml is reached. The precipitated salt is filtered off, washed with 500 ml of saturated acidified aqueous salt solution (0.1 M HCl), centrifuged, and dried. Subsequently the quantity of occluded water and bromide is measured and the d50 value determined as described above for method 1 of the test for determining whether an antisolvent exhibits crystal growth inhibiting properties. From the bromide content in the salt crystals and in the final mother liquor the partition coefficient is calculated. Said partition coefficient is the Br content in the salt crystals divided by the Br content in the mother liquor. This is the blank experiment.
The above-described procedure is repeated using 200 mg/l of an additive, and the obtained values for occluded water in the crystals, the partition coefficient, and the d50 value are compared to the ones obtained in the blank experiment. An additive is considered to be a crystal growth inhibitor if the quantity of occluded water decreases by more than 5% and/or the partition coefficient decreases by more than 5% and/or the d50 value changes by more than 5%. Moreover, if analysis by means of a (light) microscope shows crystals with (111) faces, the additive is also considered to be a crystal growth inhibitor.
2) In a stirred glass beaker, 1 l of a saturated aqueous salt solution comprising 200 mg/l of bromide is heated to reflux. The boiling solution is then saturated again by the addition of extra salt. The saturated solution is left in a hood at room temperature for 48 h. The precipitated salt is filtered off, washed with 500 ml of saturated acidified aqueous salt solution (0.1 M HCl), centrifuged, and dried. Again the quantity of occluded water, the quantity of bromide, and the d50 value are determined as described above for method 1 of the test for determining whether an antisolvent exhibits crystal growth inhibiting properties. This is the blank experiment.
The above-described procedure is repeated using 200 mg/l of an additive. The obtained values for occluded water in the crystals, the partition coefficient, and the d50 value are compared to the ones obtained in the blank experiment. An additive is considered to be a crystal growth inhibitor if the quantity of occluded water decreases by more than 5% and/or the partition coefficient decreases by more than 5% and/or the d50 value changes by more than 5%. Moreover, if analysis by means of a (light) microscope shows crystals with (111) faces, the additive is also considered to be a crystal growth inhibitor.
3) In a stirred glass beaker, 1 l of a saturated aqueous salt solution comprising 200 mg/l of bromide is left in a hood at room temperature for 1 week. The precipitated salt is filtered off, washed with 500 ml of saturated acidified aqueous salt solution (0.1 HCl), centrifuged, and dried. Again the quantity of occluded water, the quantity of bromide, and the d50 value are determined as described above for method 1 of the test for determining whether an antisolvent exhibits crystal growth inhibiting properties. This is the blank experiment.
The above-described procedure is repeated using 200 mg/l of an additive. The obtained values for occluded water in the crystals, the partition coefficient, and the d50 value are compared to the ones obtained in the blank experiment. An additive is considered to be a crystal growth inhibitor if the quantity of occluded water decreases by more than 5% and/or the partition coefficient decreases by more than 5% and/or the d50 value changes by more than 5%. Moreover, if analysis by means of a (light) microscope shows crystals with (111) faces, the additive is also considered to be a crystal growth inhibitor.

Whether or not an additive is a scaling inhibitor can be determined using one of the following four tests. If in one of these tests, preferably in two or more of these tests, and most preferably in all of these tests an additive is considered to be a scaling inhibitor, said additive is suitable for use in the process according to the present invention.
1) Additive tests for the inhibition of crystallisation and scaling of SrCO₃ and/or CaCO₃:
   a) 1 l of a saturated aqueous salt solution comprising 360 meq/l of SO₄, 2.0 meq/l of Ca, 0.1 meq/l Sr, 10 meq/l of CO₃, 6 meq/l of OH, and 120 meq/l of Br is heated to boiling point under atmospheric conditions and water is evaporated until a volume of 500 ml is obtained. The reaction mixture is filtered over a 0.2 micron filter and the quantity of dissolved Ca, Sr, and CO₃ in the mother liquor determined as described above for method 1a of the test for determining whether an antisolvent inhibits crystallisation and scaling of SrCO₃ and/or CaCO₃. This is the blank experiment. The procedure is repeated using 10 ppm of an additive. The quantities of Ca, Sr, and CO₃ in the mother liquor are now compared to the quantities of Ca, Sr, and CO₃ in the mother liquor as observed for the blank experiment. An additive is considered to be a scaling inhibitor if the quantities of dissolved Ca and/or Sr and/or CO₃ increase by more than 5%.
   b) To 1 l of a saturated aqueous salt solution comprising 360 meq/l of SO₄, 2.0 meq/l of Ca, 0.1 meq/l Sr, 10 meq/l of CO₃, 6 meq/l of OH, and 120 meq/l of Br are added 5 g of Socal® P2 ex Solvay Chemicals (i.e. CaCO₃ crystals). The mixture is heated to boiling point under atmospheric conditions and water is evaporated until a volume of 500 ml is obtained. The reaction mixture is filtered over a 0.2 micron filter and the quantities of dissolved Ca, Sr, and CO₃ in the mother liquor are determined. This is the blank experiment. The procedure is repeated using 10 ppm of an additive. The quantities of Ca, Sr, and CO₃ in the mother liquor are now compared to the quantities of Ca, Sr, and CO₃ in the mother liquor as observed for the blank experiment. An additive is considered to be a scaling inhibitor if the quantity of dissolved Ca and/or Sr and/or CO₃ increases by more than 5%.
   c) To 10 l of a saturated aqueous salt solution with a pH value of 7 comprising 75 meq/l of Ca, 2 meq/l of Sr and 75 meq/l of SO₄, and 0.1 mol of sodium carbonate is added 1 l of polyethylene glycol with Mw of about 600 g/mol, acetone, or ethanol. The salt solution is filtered on a nanofiltration membrane over a period of 15 h. The permeate flow is recycled to the side of the membrane where the antisolvent is present. After 15 h, the flux through the membrane at constant pressure is determined. This is the blank experiment. The procedure is now repeated with a saturated aqueous salt solution comprising 10 ppm of an additive. An additive is considered to be a scaling inhibitor if the flux has increased by more than 5% compared to the flux observed in the blank experiment.
d) Test for the inhibition of crystallisation and scaling of Ca and/or Sr carbonate:
The same test as test 1a, but at reflux conditions and a temperature of 90° C. and with 100 mg/l Socal® P2 seeds ex Solvay Chemicals.
e) The same test as test 1d, but without the addition of Socal® P2 seeds in the blank experiment.

Preferably test 1e is used, more preferably test 1d, even more preferably test 1c, even more preferably still test 1b, and most preferably test 1a.
2) Additive test for the inhibition of crystallisation and scaling of CaSO₄ (anhydrite): A saturated aqueous salt solution comprising 100 meq/l of Ca and 100 meq/l of SO₄ is heated to a temperature of 100° C. for 1 h with stirring in the presence of 5 g/l of anhydrite crystals. Subsequently a sample is taken which is filtered. Then the quantity of dissolved Ca and SO₄ is determined as described above for method 2 of the test for determining whether an antisolvent inhibits crystallisation and scaling of CaSO₄. This is the blank experiment. The above-described procedure is repeated using 10 ppm of an additive. An additive is considered to be a scaling inhibitor if the quantity of Ca and/or SO₄ dissolved in the mother liquor increases by more than 5%. Preferably, the pH is controlled and 10 meq/l OH is added.
3) Additive test for the inhibition of crystallisation and scaling of CaSO₄.2H₂O (gypsum): A saturated aqueous salt solution comprising 150 meq/l of Ca and 150 meq/l of SO₄ is stirred at a temperature of 20° C. for 1 h in the presence of 5 g/l of gypsum crystals. Subsequently a sample is taken which is filtered. Then the quantity of dissolved Ca and SO₄ is determined. This is the blank experiment. The above-described procedure is repeated using 10 ppm of an additive. An additive is considered to be a scaling inhibitor if the quantity of Ca and/or SO₄ dissolved in the mother liquor increases by more than 5%. Preferably, the pH is controlled and 10 meq/l OH is added.
4) Additive test as described in S. Patel, M. A. Finon, Desalination 124 (1999) 63-74, where the inhibition is more than 5%.

If a crystal growth inhibitor and/or scaling inhibitor are added to the antisolvent(s), said crystal growth inhibitor and/or said scaling inhibitor are to be used in the process according to the present invention in an effective quantity. An effective quantity of crystal growth inhibitor is present if the quantity of occluded water in the salt crystals decreases by more than 5% and/or the partition coefficient decreases by more than 5% and/or the d50 value increases by more than 5% compared to salt produced from the same salt solution under the same conditions, but without the addition of a crystal growth inhibitor. An effective quantity of scaling inhibitor is present if the quantity of dissolved Ca and/or Sr and/or SO₄ and/or CO₃ in the mother liquor changes by more than 5% compared to mother liquor produced from the same salt solution under the same conditions, but without the addition of a scaling inhibitor.

If a crystal growth inhibitor is employed in the process according to the present invention, typically, the quantity of said crystal growth inhibitor present in the mother liquor-antisolvent system is less than 5,000 mg per kg of mother liquor. Preferably, less than 1,500 mg/kg and more preferably less than 300 mg/kg is used. However, concentrations of crystal growth inhibitor higher than 5,000 mg per kg mother liquor are also possible. Typically, more than 10 mg, preferably more than 12.5 mg, and most preferably more than 14 mg of crystal growth inhibitor is used per kg of mother liquor.

If a scaling inhibitor is employed in the process according to the present invention, typically, the quantity of said scaling inhibitor present in the mother liquor-antisolvent system is less than 5,000 mg per kg of mother liquor as well. Preferably, less than 1,500 mg/kg and more preferably less than 300 mg/kg is used. However, concentrations of scaling inhibitor higher than 5,000 mg per kg mother liquor are also possible. Typically, more than 1 mg, preferably more than 3 mg, and most preferably more than 5 mg of scaling inhibitor is used per kg of mother liquor.

Preferably, only one antisolvent is employed. More preferably, an antisolvent is used which exhibits crystal growth inhibiting properties and/or scaling inhibiting properties, optionally in combination with one or more scaling inhibitors and/or crystal growth inhibitors. The antisolvent may be, but is not necessarily, (partially) miscible with pure water. It is also possible to use an antisolvent or mixture of antisolvents which will result in the formation of an emulsion after it/they are added to the aqueous salt solution. Preferably, an antisolvent or mixture of antisolvents is used which is partially miscible with the aqueous salt solution because such antisolvent(s) can be recovered by a temperature induced liquid-liquid separation. I.e. the system has two liquid phases below a certain critical temperature or above a certain critical temperature. Phase-separation of the water layer and the antisolvent can then be a temperature induced phase-separation as is generally known in the art. Most preferably, the antisolvent(s) used in the process according to the present invention is/are environmentally friendly, and preferably, it/they is/are also food grade. Moreover, the preferred antisolvents are solvents which are cheap and readily available.

The choice of the one or more antisolvents depends on the solubility characteristics of the salt being crystallised. Antisolvents which exhibit crystal growth inhibiting and/or scale inhibiting properties for brine crystallisation processes are preferably selected from the group consisting of aliphatic or aromatic alcohols, nitrilotriacetic acid, carboxylic acids or polycarboxylic acids, phosphonates, polyphosphonates, functionalised or unfunctionalised carboxymethyl cellulose, organocomplexes of Fe(II) and Fe(III) ions, ethanol, acetone, isopropanol, quaternary ammonium salts, cyclodextrines, polymers bearing amino groups, polymers bearing quaternary ammonium groups, polymers comprising nitrogen-containing aliphatic rings, sodium salts of polymers bearing anionic groups, and chloride salts of polymers bearing cationic groups. More preferably, polyvinyl alcohol, polyethylene glycol, or choline chloride is employed.

In a particularly preferred embodiment, ionic liquids are employed as the antisolvent(s). Examples of ionic liquids suitable for use as an antisolvent in the process according to the present invention include but are not limited to choline chloride based ionic liquids such as choline chloride/urea, choline chloride/phenol, or choline chloride/saccharide. Most preferably, ionic liquids are used which are nitrogen-free.

Crystal growth inhibitors suitable for use in the process of antisolvent crystallisation of a salt include all conventional crystal growth inhibitors. Preferably, the crystal growth inhibitor for a brine crystallisation process is selected from the group consisting of oligopeptides, polypeptides, and polymers bearing two or more carboxylic acid groups or carboxyalkyl groups and optionally also phosphate, phosphonate, phosphino, sulfate and/or sulfonate groups; functionalised or unfunctionalised monosaccharides, disaccharides, and polysaccharides; ferrocyanide salts; lead chloride; cadmium chloride; manganese sulfate; quaternary ammonium salts; cyclodextrines; polymers bearing amino groups; polymers bearing quaternary ammonium groups; polymers comprising nitrogen-containing aliphatic rings; sodium salts of polymers bearing anionic groups; and chloride salts of polymers bearing cationic groups. Most preferably, the crystal growth inhibitor is selected from the group consisting of polymaleic acid, polyacrylates, glycose, saccharose, and urea. In the preferred, closed loop antisolvent crystallisation process according to the present invention, preferably a crystal growth inhibitor is used which will not pass the membrane in the nanofiltration step. Instead, it will remain in the antisolvent stream, which is subsequently recycled to the crystalliser/settler.

It was also found that by adding the crystal growth inhibitor according to the invention to the antisolvent during the production process of salt, the crystal size distribution could be influenced. It appeared that increasing quantities of crystal growth inhibitor in the antisolvent resulted in the production of smaller crystals. Preferably, the d50 crystal diameter, i.e. the diameter at which 50 wt % of the crystals have a larger crystal diameter and 50 wt % of the crystals have a smaller crystal diameter, can be shifted by more than 10% compared to the size of crystals grown in the absence of a crystal growth inhibitor just by adapting the quantities of crystal growth inhibitor in the antisolvent. The crystal size distribution could be determined by means of conventional techniques such as sieve analysis or using a light microscope.

Furthermore, it was found that by using the antisolvent process according to the present invention it becomes relatively easy to influence the modification (i.e. the type of crystal lattice) of the crystals which are obtained.

Scaling inhibitors suitable for use in the process of antisolvent crystallisation of a salt include any conventional scaling inhibitor. Preferably, the scaling inhibitor for a brine crystallisation process is selected from the group consisting of oligopeptides, polypeptides, polymers bearing 2 or more carboxylic acid groups or ester groups, and optionally also phosphate, phosphonate, phosphino, sulfate and/or sulfonate groups, functionalised or unfunctionalised mono-saccharides, disaccharides, polysaccharides, polymers with one or more alcohol groups, humic acids, surfactants from a natural source such as disproportionated rosin acid soap, lactic acid, phospholipids, a suspension of yeast cells, a suspension of algae, N,N-diethyl-1,3-diaminopropane, ethylene diamine, polyisobutylene derivatives, N,N-dimethyl-1,3-diaminopropane, diethylene triamine, triethylene tetramine, 1,6-diaminohexane, poly[oxy(methyl-1,2-ethanediyl)], hexamethylene biguanide, maleic anhydride homopolymer, amylase, protease, sodium citrate, citric acid, N,N,N′,N′-tetraacetylethylene diamine, nonanoyloxybenzene sulfonate, polyepoxysuccinic acid, polyacrylamide, ethylenediamine tetramethylene phosphonic acid, sulfonated polyoxyethylene ethers, quaternary ammonium salts, cyclodextrines, polymers bearing amino groups, polymers bearing quaternary ammonium groups, polymers comprising nitrogen-containing aliphatic rings, sodium salts of polymers bearing anionic groups, chloride salts of polymers bearing cationic groups, fatty acids, orange juice, apple juice, polyethylene imine, sodium dimethyl dithiocarbamate, and Fe(II) or Fe(III) iron complexes with one of the above-mentioned scaling inhibitors. Most preferably, the scaling inhibitor is selected from the group consisting of polyacrylates, polyphosphates, sucrose, and sodium gluconate.

For the water in the present process, any water supply normally used in conventional salt crystallisation processes can be employed. In the preferred, closed loop antisolvent crystallisation process according to the present invention, only small quantities of water are needed. First, water is needed to start the crystallisation process by dissolving part of the salt source. During the process, an aqueous salt slurry is removed from the crystalliser/settler. A quantity of water which preferably equals the quantity of water lost via the aqueous salt slurry is then added to the salt source in order to allow continuation of the process. The quantity of water needed in order to preserve a continuous crystallisation process can be lowered even further if the recycle of the centrifuge, to which the crystallised salt in an aqueous slurry is preferably fed, is recycled into the crystalliser/settler and/or to the salt source.

In a specially preferred embodiment of the present invention, the salt source is a subterraneous sodium chloride deposit in a well exploited by means of dissolution mining. In a closed loop process, the undersaturated aqueous salt solution which is removed from the nanofiltration unit and recycled to the sodium chloride deposit will contain certain levels of contaminants, such as K, Br, SO₄, Mg, Sr, and/or Ca contaminations. When it is recycled to the sodium chloride, it will not only become saturated with sodium chloride, but contaminations present in the deposit will also dissolve. As a consequence, the concentrations of said contaminations in the saturated aqueous salt solution leaving the sodium chloride deposit will increase during the process until said solution is also saturated with these contaminations. As a result, a stationary phase will be reached in which there is no driving force anymore for new contaminations present in the sodium chloride deposit to dissolve in the aqueous solution. In the described preferred embodiment, addition of water is only needed to fill the cavity which is formed upon dissolution of the natural salt source.

It is known that the purity of aqueous salt solutions in evaporation processes can be increased by reducing the quantity of the contaminations, such as anhydrite, gypsum, and polyhalite (and/or their strontium analogues), that dissolve in said aqueous solutions. This is typically done by adding certain agents to the water used in the process, or by mixing such agents with the salt source before adding the water. Such agents are conventionally called “retarding agents.” Although such agents are not required for the production of high-purity salt via the process of the present invention, if desired, these types of additives may be added to the water supply.

The nanofiltration unit used in the process according to the present invention may comprise any conventional membrane which is able to separate the one or more antisolvents and the aqueous salt solution. The separation can be based upon molecular dimensions and/or upon electrostatic repulsion. Preferably, the separation is based on molecular dimensions only. In a particularly preferred embodiment, a membrane is used which is permeable to salt and to the contaminations present in the aqueous solution, but not for antisolvent. Preferably, the membrane is 75-100% selective for the separation of the antisolvent and the aqueous salt solution. More preferably, the membrane is 85-100% selective, even more preferably 95-100% selective, and most preferably 99.9-100% selective, in order to limit the quantity of antisolvent which will leave the nanofiltration unit together with the undersaturated aqueous salt solution. Antisolvent which does pass the membrane ends up in the undersaturated aqueous salt solution stream, from which it is removed from the system, or, in the preferred embodiment, recycled to the salt source. In the latter case, the undersaturated aqueous salt solution comprising some antisolvent is saturated again and returned to the crystalliser/settler unit as the saturated aqueous salt solution. Hence, the loss of antisolvent from the closed loop process will be insignificant. Depending on the properties of the antisolvent, the types, and the concentration of the contaminants in the aqueous salt solution to be filtered, and the characteristics of the membrane, the optimum process temperature may vary. Typical temperatures for the separation of antisolvent and aqueous salt solution range from −10 to 110° C.

The crystalliser/settler suitable for use in the process according to the present invention may be any conventional crystalliser/settler. Preferably, it is a crystalliser/settler with a vertical feed hose system and no impeller or other moving parts, which comprises a continuous phase in the crystalliser containing the one or more antisolvents so that the salt will crystallise continuously. More preferably, the crystalliser/settler is a reactor for precipitating and/or crystallising a substance comprising at least a bottom wall, a vertical wall preferably having a cylindrical cross-section, at least a first inlet, preferably at least first and second inlets for feeding first and second reactants to the reactor, and an outlet. Such a crystalliser/settler is for example described in U.S. Pat. No. 4,747,917. However, most preferably, a crystalliser/settler is used wherein the one or more inlets comprise respective discharge openings arranged to direct the reactants to a surface and cause them to collide with the same, which is for example disclosed in NL 7215309.

The crystallised salt is removed from the crystalliser/settler as an aqueous slurry. Preferably, it is fed to a centrifuge, where a wet salt is produced. The term “wet salt” is used to denominate salt containing a substantial quantity of water. More particularly, it is water-containing salt of which more than 50 wt % consists of the pure salt. Preferably, such salt contains more than 90 wt % of the pure salt. More preferably, the salt contains more than 92 wt % of the pure salt, while a salt of essentially the pure salt and water is most preferred. The wet salt will contain more than 0.5, preferably more than 1.0, more preferably more than 1.5 wt % of water. Preferably, it contains less than 10 wt %, more preferably less than 6 wt %, and most preferably less than 4 wt % of water. All of the weight percentages given are based on the weight of the total composition. If desired, the wet salt may be dried in a conventional manner to obtain dried salt comprising less than 0.5 wt % of water.

In a particularly preferred embodiment according to the present invention, the process further comprises a reverse osmosis step before the overflow of the crystalliser/settler comprising antisolvent(s), water, and salt is fed to a nanofiltration unit. In said osmosis step, water is removed from the mixture of the aqueous solution comprising the salt and the antisolvents, thus resulting in a more concentrated aqueous component. As a consequence, more of the salt will be forced to crystallise out.

The process of osmosis is well-known and may be defined in general terms as the diffusion which proceeds through a semipermeable membrane separating two solutions comprising a solute in unequal concentrations. By means of diffusion of one of the solvents into the other solution, the concentration of the solute in each solution will be equalised. For example, in the osmosis operation pure water will diffuse from a first aqueous solution having a lower solute concentration through the semipermeable membrane into a second aqueous solution having a higher solute concentration. When the second aqueous solution is subjected to an elevated hydraulic pressure relative to the hydraulic pressure existing in the first solution, diffusion of the water through the membrane is restrained. The pressure at which diffusion into the second solution is substantially halted is the osmotic pressure. If the hydraulic pressure applied to the second solution is further increased relative to that of the first solution so that the osmotic pressure of the second solution is exceeded, reverse osmosis occurs, i.e. water from the second aqueous solution diffuses through the membrane into the first aqueous solution. For example, the osmotic pressure of saturated brine relative to water is approximately 300 bars. This means that for reverse osmosis, hydraulic pressures higher than 300 bars are required to crystallise salt. Such high pressures require special equipment. Moreover, high energy costs are involved. However, when an antisolvent is added to the brine, the solubility of the salt will decrease. As a consequence, the osmotic pressure will also decrease, resulting in a more economic process. In said particularly preferred embodiment of the process according to the present invention, a solution which essentially consists of water is used as a first solution, whereas for the second solution use is made of the overflow of the crystalliser/settler comprising antisolvent(s), water, and salt. The pressure applied to the second solution preferably is such that water will diffuse into the first solution. The pressure at which said reverse osmosis takes place is generally dependent upon the composition of the second solution. Normally, pressures between 1-250 bars, preferably 5-150 bars are required. More preferably, pressures between 8-100 bars are applied, even more preferably pressures between 10-80 bars, and most preferably pressures between 10-50 bars are applied. The first solution preferably is water of high quality which can be used as drinking water and/or process water, or, if so desired, may be safely discharged into streams, rivers, lakes, and the like, without additional treatments. It is noted that the antisolvent-membrane technology according to the invention is suitable for the production of drinking water or process water from aqueous solutions comprising salt, using one or more antisolvents. Especially in regions where water is very scarce, reverse osmosis up to very high concentrations of the second solution is desired.

The economical feasibility of the process according to the present invention depends on the pressure required to filter the brine through the nanofiltration unit or the reverse osmosis unit. It is noted that the pressure required for the reverse osmosis step can be strongly reduced when the first solution, which comprises water, is combined with a waste stream comprising alkali and/or alkaline earth salts, such as raw brine or an ion-comprising waste stream of a different process. Preferably, said waste stream may be safely discharged into streams, rivers, lakes, and the like, without additional treatments. Therefore, in a preferred embodiment according to the present invention, the process further comprises a reverse osmosis step wherein water from a second solution, comprising at least part of the overflow of the crystalliser/settler, diffuses into a first solution, which comprises water and a waste stream comprising alkali and/or alkaline earth salts.

Preferably, after the reverse osmosis step, 5-40 wt %, more preferably 10-25 wt % of the second solution is recycled into the crystalliser/settler, whereas 95-60 wt %, more preferably 90-75 wt % is fed to the nanofiltration unit. Feeding part of said second solution to the crystalliser/settler has the advantage that the supersaturation level in the overflow of the crystalliser/settler will decrease, so that the quantity of salt which crystallises during the reverse osmosis step will be lowered. It is noted that if the antisolvent exhibits crystallisation inhibiting properties and/or comprises one or more crystal growth inhibitors, nucleation will be inhibited, which will also help to reduce the quantity of salt which will crystallise during the reverse osmosis step.

The semipermeable membrane to be used in the reverse osmosis step according to the invention can be any conventional semipermeable membrane which has a definite permeability to water, while at the same time it is impermeable to the contaminants present in the aqueous solution and the antisolvents used. Preferably, the semipermeable membrane has a permeability of less than 25% to antisolvent and contaminants, more preferably less than 15%, even more preferably less than 5%, and most preferably less than 0.1%. In the reverse osmosis step preferably at least 10 wt % of water, based on the total weight of the aqueous solution comprising the salt, is removed. More preferably, at least 50 wt % of water, even more preferably at least 75 wt % and most preferably at least 99 wt % of water, based on the total weight of the aqueous solution comprising the salt, is removed.

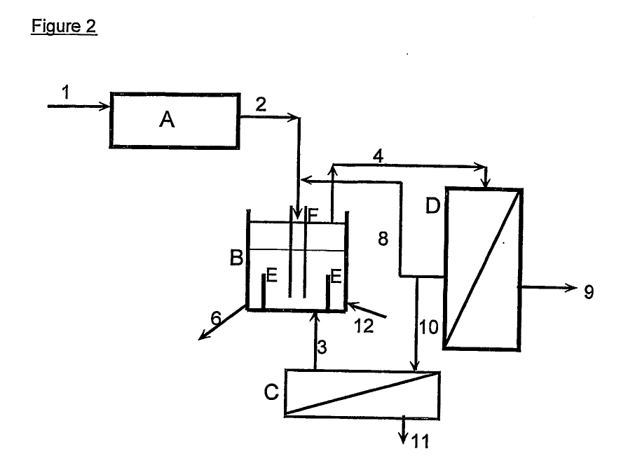

In a further optimised embodiment of the above-described process according to the present invention, preferably, a slightly adapted crystalliser/settler is used. In addition, the process is slightly adapted. For a schematic depiction of a flow chart for said embodiment see FIG. 2.

In said optimised process according to the invention, water (1) is fed to a salt source (A), where it dissolves at least part of the salt. When the salt solution, which is preferably saturated, comes out of the salt source (2), it is fed to a conventional crystalliser/settler (B). One or more antisolvents (3) are also fed to the crystalliser/settler (B). Settler (B) preferably comprises an inlet pipe (F) and a partition wall (E) having a circular cross-section which is placed on the bottom wall, surrounding the lower end of the inlet pipe (F). The partition wall (E) has the effect of creating an upward flow, which causes the slurry to eddy. It is preferred that the height of the partition wall is less than 60%, preferably less than 50% of the effective height of the settler (B), since in such configurations the slurry above the partition wall (E) will eddy in a direction opposite to the flow within the partition wall (E), thus enhancing the settling of solids. The formed crystalline composition will settle in the space between the partition wall (E) and the side wall of the settler and is removed, in the form of a salt slurry, via one or more outlets (6) in the bottom part of the side wall. Preferably, the salt slurry is fed to a centrifuge. Since said salt slurry that is removed from the crystalliser/settler (B) by one or more outlets (6) may still contain relatively large quantities of antisolvent, most preferably, before said salt slurry is fed to a centrifuge, it is fed to a washing leg, where a raw aqueous salt solution or a purified aqueous salt solution is used as washing medium. Especially if the salt slurry is to be used for electrolysis purposes, it is important to wash the adhered mother liquor and/or antisolvent from the salt crystals. However, in a preferred embodiment, the washing step is executed in the crystalliser/settler (B) by feeding (part of) the solution coming out of the source (2) to the crystalliser/settler (B) near the bottom in the space between the partition wall (E) and the side wall of the settler. This way, the slurry removed from the crystalliser/settler is washed continuously with fresh antisolvent-free raw aqueous salt solution. Consequently, the salt slurry that is removed from the crystalliser/settler by the one or more outlets (6) is already free of antisolvent(s) prior to being sent to the centrifuge. It is noted that the salt can be washed in an additional washing leg or on the centrifuge to remove contaminations dissolved in the solution coming out of the source (2).

The overflow (4) of the crystalliser/settler comprising antisolvent(s), water, and salt is fed to the reverse osmosis unit (D), where part of the water which has dissolved in the antisolvent is removed. Produced demineralised water (9) is removed from the reverse osmosis unit (D), whereas 0-50 wt %, preferably 5-40 wt %, more preferably 10-25 wt % of the concentrated antisolvent stream leaving the reverse osmosis unit is fed (8) to the inlet pipe (F) of the settler (B), and 100-50 wt %, preferably 95-60 wt %, more preferably 90-75 wt % is fed (10) to the nanofiltration unit (C) comprising a membrane wherein the one or more antisolvents are separated from the water and any salt still present in the antisolvent stream. Preferably, as described above, the membrane is permeable to the salt and to the contaminations present in the antisolvent stream, but not to antisolvent. After the separation, the purge (11) comprising water and dissolved salt and contaminations and the antisolvent (3) are removed from the nanofiltration unit. Preferably, the purge (11) does not exceed 20 wt %, more preferably 10 wt % of the total weight of the stream (2) which was fed to the crystalliser/settler. Preferably, the recovered antisolvent (3) from the nanofiltration unit is reused by being recycled to the crystalliser/settler.

Furthermore, in a special, optimised embodiment of the present invention, preferably one or more hydrophilic antisolvents are used which form a two-phase system with pure water. By “hydrophilic antisolvent” is meant an antisolvent as defined above which will take up at least 5 wt % of water, more preferably at least 10 wt % of water, and most preferably at least 20 wt % of water, based on the total weight of the antisolvent. The hydrophilic antisolvent preferably does not take up more than 60 wt % of water, more preferably 50 wt % of water, and most preferably 40 wt % of water, based on the total weight of the antisolvent. Such a hydrophilic antisolvent will extract water from the aqueous solution comprising the salt, thus forcing said salt to crystallise. In a preferred embodiment, a hydrophilic antisolvent is applied which has a density of less than 1,200 kg/m³, even more preferably of less than 1,150 kg/m³, and most preferably of less than 1,125 kg/m³. In that case, a two-phase system will be formed inside the crystalliser/settler (B), with the overflow of the crystalliser/-settler (B) being mostly antisolvent comprising water. As is known in the literature, only a small quantity of the salt will dissolve in said antisolvent/water phase. In said preferred process the overflow of the crystalliser/setller is fed to the nanofiltration unit (C) wherein the antisolvent(s) are separated from the aqueous solution. Preferably, the recovered antisolvent(s) are recycled to the crystalliser/settler (B), whereas the recovered aqueous solution can be drained off. Preferred hydrophilic antisolvents include but are not limited to choline chloride/phenol ionic liquid and polypropylene glycol.

It is furthermore possible to feed said overflow to the reverse osmosis unit as described above. Due to the fact that the osmotic pressure of the antisolvent/water mixture in the overflow relative to water is now drastically lowered, such a reverse osmosis step will be even more economic.

In said reverse osmosis step, preferably at least 10 wt % of the total quantity of water dissolved in the antisolvent stream which is fed to the reverse osmosis unit is removed. More preferably, at least 50 wt % of the total quantity of water, even more preferably at least 75 wt % of the total quantity of water dissolved in the antisolvent stream which is fed to the reverse osmosis unit is removed. Preferably, to prevent crystallisation of the salt present in said antisolvent stream, at most 90 wt % of the total quantity of dissolved water is removed in the reverse osmosis step.

It is noted that any additive suitable for improving the flux of the membrane in the nanofiltration unit and/or of the reverse osmosis membrane by preventing the membrane from fouling may be added to the antisolvent(s) and/or the aqueous salt solution. Preferably, surfactants are added to the antisolvent in order to increase the flux of the membrane(s).

In a specially preferred embodiment the salt is sodium chloride. (Wet) sodium chloride according to the present invention is preferably used to prepare brine for electrolysis processes and most preferably for the modern membrane electrolysis processes. The sodium chloride produced in the above-described manner can also be used for consumption purposes. It is for instance suitable as table salt.

The present invention is elucidated by means of the following non-limiting Examples.

In said examples, a raw brine sample from the brine field in Hengelo, The Netherlands, was used as the sodium chloride source.

### EXAMPLE 1

The following model experiments were performed for the antisolvent crystallisation of sodium chloride using polyethylene glycol.

For this purpose, 4 aqueous solutions saturated in crude sodium chloride (brine) were prepared to which polyethylene glycol (PEG) with a molecular weight of about 600, hereinafter called PEG600, was added in a quantity of 5 wt %, 10 wt %, 25 wt %, and 50 wt %, respectively. The precipitated sodium chloride was filtered off and dried.

TABLE 1

| Sample | PEG (wt %) | Yield of NaCl (g) per liter of brine |
|---|---|---|
| 1 | 5 wt % | 4 |
| 2 | 10 wt % | 12 |
| 3 | 25 wt % | 26 |
| 4 | 50 wt % | 41¹ |

¹In this case not only NaCl precipitated from the solution, but a small quantity of CaSO₄ precipitated as well.

The quantities of dissolved Ca, Mg, SO₄, K, and Br were determined in samples 3 and 4 by means of ICP (Inductively Coupled Plasma) spectrometry. The results are summarised in Table 2 and compared to the quantities of contaminations present in electrolysis (vacuum) salt.

TABLE 2

| | Sample 3 | Sample 4 | Electrolysis salt |
|---|---|---|---|
| Contaminant | (mg/kg NaCl) | (mg/kg NaCl) | (mg/kg NaCl) |
| Ca | 35 | 156 | 1.2 |
| Mg | 0.23 | 2.0 | 0.23 |
| SO₄ | 82 | 1310 | 75 |
| K | 69 | 44 | 69 |
| Br | 3.5 | 1.2 | 28 |

As can be derived from Tables 1 and 2, polyethylene glycol not only functions as an antisolvent, it also exhibits crystal growth inhibiting properties. Especially the concentrations of K and Br are significantly lower than in normal electrolysis (vacuum) salt.

### EXAMPLE 2

A solution was prepared from:

21.55 kg crude sodium chloride (75 wt %)

7.11 kg PEG600 (25 wt %)

After the addition of PEG600, crystallisation of sodium chloride was observed. The crystallised sodium chloride was filtered off and the mother liquor was fed to a nanofiltration unit comprising a tubular shaped nanofiltration membrane of the type PCI AFC30 ex PCI.

TABLE 3

| | | | | PEG600 | PEG600 | |
|---|---|---|---|---|---|---|
| | | | | in | in | |
| Temperature | Pressure | Flux | | concentrate | permeate | R |
| (° C.) | (bar) | (kg/m².h) | CF | (g/l) | (g/l) | (%) |
| 36 | 38 | 6.9 | 1 | 451 | 89 | 80 |

The experiment was performed under recycle conditions, i.e. the total permeate stream was fed back to the pressure side of the membrane. Hence, the CF, i.e. the concentration factor, is 1.

R, the retention factor, was calculated as follows:

$$100 - [ \frac{\{ PEG600 concentration in permeate \}}{\{ PEG600 concentration in concentrate \}} * 100 ]$$

From this experiment it can be concluded that PEG600 is an antisolvent that can be retained by a nanofiltration membrane.

1. A process involving the use of an antisolvent comprising the steps of
feeding water to an inorganic salt source to form an aqueous solution comprising said salt,
feeding said aqueous solution to a crystalliser/settler,
contacting said aqueous solution with one or more antisolvents which force the salt to at least partly crystallise, with at least one of said antisolvents exhibiting crystal growth inhibiting properties and/or scaling inhibiting properties,
and where if the antisolvents do not exhibit sufficient crystal growth inhibiting properties and/or sufficient scaling inhibiting properties, one or more crystal growth inhibitors are added to the antisolvents and/or to the aqueous solution, and/or one or more scaling inhibitors are added to the antisolvents and/or to the aqueous solution,
feeding an overflow of the crystalliser/settler comprising one or more antisolvents and an aqueous salt solution to a nanofiltration unit comprising a membrane to separate the one or more antisolvents from the aqueous salt solution,
removing the crystallised salt from the crystalliser/settler in an aqueous slurry,
optionally, recycling the one or more antisolvents to the crystalliser/settler, and
optionally, recycling water from the slurry to the first dissolution step and/or to the crystalliser/settler.

2. A process according to claim 1 wherein at least part of the overflow of the crystalliser/settler is subjected to a reverse osmosis step before it is fed to the nanofiltration unit.

3. A process according to claim 2 wherein in the reverse osmosis step 10-99 wt % of water, based on the total weight of the aqueous solution comprising the salt, is removed.

4. A process according to claim 3 wherein the removed water is used as drinking or process water.

5. A process according to claim 1 which is a continuous closed loop process, wherein the aqueous salt solution which leaves the nanofiltration unit is recycled to the salt source.

6. A process according to claim 1 wherein the crystallised salt in an aqueous slurry is fed to a centrifuge, optionally after being fed to a washing leg.

7. A process according to claim 6 wherein the recycle of the centrifuge is fed to the crystalliser/settler and/or to the salt source.

8. A process according to claim 1 wherein the salt source is selected from the group consisting of a sodium chloride, sodium carbonate, and sodium sulfate source.

9. A process according to claim 8 wherein the salt source is a subterraneous sodium chloride deposit.

10. A process according to claim 1 wherein the antisolvent is selected from the group consisting of aromatic alcohols, polyvinyl alcohol, polyethylene glycol, nitrilotriacetic acid, carboxylic acids or polycarboxylic acids, phosphanates, polyphosphonates, functionalised or unfunctionalised carboxymethyl cellulose, organocomplexes of Fe(II) and Fe(III) ions, ethanol, acetone, isopropanol, quaternary ammonium salts, cyclodextrines, polymers bearing amino groups, polymers bearing quaternary ammonium groups, polymers comprising nitrogen-containing aliphatic rings, sodium salts of polymers bearing anionic groups, and chloride salts of polymers bearing cationic groups, choline chloride, and choline chloride based ionic liquids.

11. A process according to claim 1 wherein the antisolvent comprises at least one crystal growth inhibitor selected from the group consisting of oligopeptides, polypeptides, and polymers bearing two or more carboxylic acid groups or carboxyalkyl groups and optionally also phosphate, phosphonate, phosphino, sulfate and/or sulfonate groups; functionalised or unfunctionalised monosaccharides, disaccharides, and polysaccharides; potassium ferrocyanide; lead chloride; cadmium chloride; manganese sulfate; quaternary ammonium salts; cyclodextrines; polymers bearing amino groups; polymers bearing quaternary ammonium groups; polymers comprising nitrogen-containing aliphatic rings; sodium salts of polymers bearing anionic groups; and chloride salts of polymers bearing cationic groups.

12. A process according to claim 1 wherein the antisolvent comprises a scaling inhibitor selected from the group consisting of oligopeptides, polypeptides, polymers bearing 2 or more carboxylic acid groups or ester groups, and optionally also phosphate, phosphonate, phosphino, sulfate and/or sulfonate groups, functionalised or unfunctionalised monosaccharides, disaccharides, polysaccharides, polymers with one or more alcohol groups, humic acids, surfactants from a natural source such as disproportionated rosin acid soap, lactic acid, phospholipids, a suspension of yeast cells, a suspension of algae, N,N-diethyl-1,3-diaminopropane, ethylene diamine, polyisobutylene derivatives, N,N-dimethyl-1,3-diaminopropane, diethylene triamine, triethylene tetramine, 1,6-diaminohexane, poly[oxy(methyl-1,2-ethanediyl)], hexamethylene biguanide, maleic anhydride homopolymer, amylase, protease, sodium citrate, citric acid, N,N,N′,N′-tetraacetylethylene diamine, nonanoyloxybenzene sulfonate, polyepoxysuccinic acid, polyacrylamide, ethylenediamine tetramethylene phosphonic acid, sulfonated polyoxyethylene ethers, quaternary ammonium salts, cyclodextrines, polymers bearing amino groups, polymers bearing quaternary ammonium groups, polymers comprising nitrogen-containing aliphatic rings, sodium salts of polymers bearing anionic groups, chloride salts of polymers bearing cationic groups, fatty acids, orange juice, apple juice, polyethylene imine, sodium dimethyl dithiocarbamate, and Fe(II) or Fe(III) iron complexes with one of the above-mentioned scaling inhibitors.

13. A process according to claim 1 wherein the one or more antisolvents or the one or more crystal growth inhibitors have scale inhibiting properties.

14. A process according to claim 1 wherein a hydrophilic antisolvent is used which will take up at least 5 wt % of water, based on the total weight of the antisolvent.
